(19) United States
(12) Patent Application Publication
(10) Pub. No.: US 2024/0203780 A1
(43) Pub. Date: Jun. 20, 2024

(54) DIELECTRIC FILLED ALIGNMENT MARK STRUCTURES

(71) Applicant: International Business Machines Corporation, Armonk, NY (US)

(72) Inventors: Somnath Ghosh, Clifton Park, NY (US); Ruilong Xie, Niskayuna, NY (US); Stuart Sieg, Albany, NY (US); Fee Li Lie, Albany, NY (US); Kisik Choi, Watervliet, NY (US)

(21) Appl. No.: 18/083,380

(22) Filed: Dec. 16, 2022

(51) Int. Cl. H01L 21/683; H01L 23/544

(52) U.S. Cl. CPC H01L 21/6835; H01L 23/544; H01L 2221/68309; H01L 2221/68327; H01L 2223/54426

(57) ABSTRACT

A semiconductor structure includes a handler substrate and a device substrate bonded to the handler substrate. The handler substrate comprises a trench, and at least one alignment mark in a bottom surface of the trench. One or more dielectric layers are disposed in the trench and on the at least one alignment mark.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming a diffusion break structure for a semiconductor device.

In one embodiment, a semiconductor structure includes a semiconductor substrate comprising a trench, at least one alignment mark in a bottom surface of the trench, and one or more dielectric layers disposed in the trench and on the at least one alignment mark.

In another embodiment, a method of forming a semiconductor device includes forming a trench in a semiconductor substrate, forming at least one alignment mark in a bottom surface of the trench, and forming one or more dielectric layers in the trench on the at least one alignment mark.

In another embodiment, a semiconductor structure includes a handler substrate and a device substrate bonded to the handler substrate. The handler substrate comprises a trench, and at least one alignment mark in a bottom surface of the trench. One or more dielectric layers are disposed in the trench and on the at least one alignment mark.

These and other features and advantages of embodiments described herein will become more apparent from the accompanying drawings and the following detailed description.

### BRIEF DESCRIPTION OF THE DRAWINGS

FIG. 1 is a schematic cross-sectional view illustrating a semiconductor substrate, according to an embodiment of the invention.

FIG. 2 is a schematic cross-sectional view illustrating a plurality of dielectric layers formed on the semiconductor substrate from FIG. 1, according to an embodiment of the invention.

FIG. 3 is a schematic cross-sectional view illustrating an organic planarization layer (OPL) and a lithography stack formed on the plurality of dielectric layers from FIG. 2, according to an embodiment of the invention.

FIG. 4 is a schematic cross-sectional view illustrating formation of a trench in the semiconductor substrate and removal of the lithography stack from the semiconductor structure of FIG. 3, according to an embodiment of the invention.

FIG. 5 is a schematic cross-sectional view illustrating removal of the OPL layer from the semiconductor structure of FIG. 4, according to an embodiment of the invention.

FIG. 6 is a schematic cross-sectional view illustrating formation of a plurality of dielectric layers in the trench of and on the semiconductor structure of FIG. 5, according to an embodiment of the invention.

FIG. 7 is a schematic cross-sectional view illustrating planarization of the semiconductor structure of FIG. 6, according to an embodiment of the invention.

FIG. 8 is a schematic top view illustrating an alignment mark in the trench of the semiconductor structure of FIG. 7, according to an embodiment of the invention.

FIG. 9 is a schematic cross-sectional view illustrating bonding of device and handler substrates, according to an embodiment of the invention.

FIG. 10 is a schematic cross-sectional view illustrating edge trimming of a device substrate, according to an embodiment of the invention.

FIG. 11 is a schematic cross-sectional view illustrating grinding of a device substrate, according to an embodiment of the invention.

FIG. 12 is a schematic cross-sectional view illustrating planarization of a device substrate, according to an embodiment of the invention.

FIG. 13 is a schematic cross-sectional view illustrating removal of a device substrate, according to an embodiment of the invention.

FIG. 14 is a schematic cross-sectional view illustrating removal of a buried dielectric layer, according to an embodiment of the invention.

### DETAILED DESCRIPTION

Illustrative embodiments of the invention may be described herein in the context of illustrative methods for forming alignment marks in trenches filled with one or more dielectric layers, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers may be used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nanometers and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nanometers and beyond), next-generation complementary FET (CFET) devices may be used. CFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. CFET structures provide improved track height scaling, leading to structural gains (e.g., such as 30-40% structural gains for different types of devices, such as logic devices, static random-access memory (SRAM) devices, etc.). In CFET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation CFET devices.

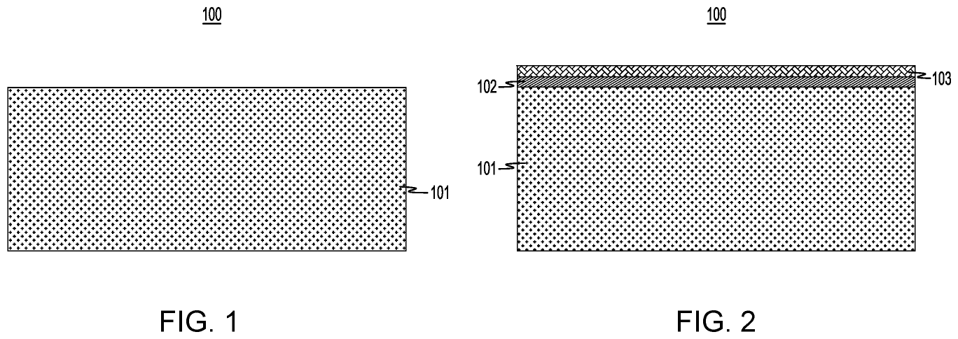

Referring to FIG. 1, a semiconductor structure 100 comprises a semiconductor substrate 101 including semiconductor material including, but not limited to, silicon (Si), silicon germanium (SiGe), silicon carbide (SiC), Si:C (carbon doped silicon), silicon germanium carbide (SiGeC), carbon doped silicon germanium (SiGe:C), III-V, II-V compound semiconductor or other like semiconductor. In addition, multiple layers of the semiconductor materials can be used as the semiconductor material of the substrate. The semiconductor substrate 101 can be a bulk substrate or a semiconductor-on-insulator substrate such as, but not limited to, a silicon-on-insulator (SOI), silicon-germanium-on-insulator (SGOI) or III-V-on-insulator substrate including a buried insulating layer, such as, for example, a buried oxide layer, buried nitride layer or buried aluminum oxide layer.

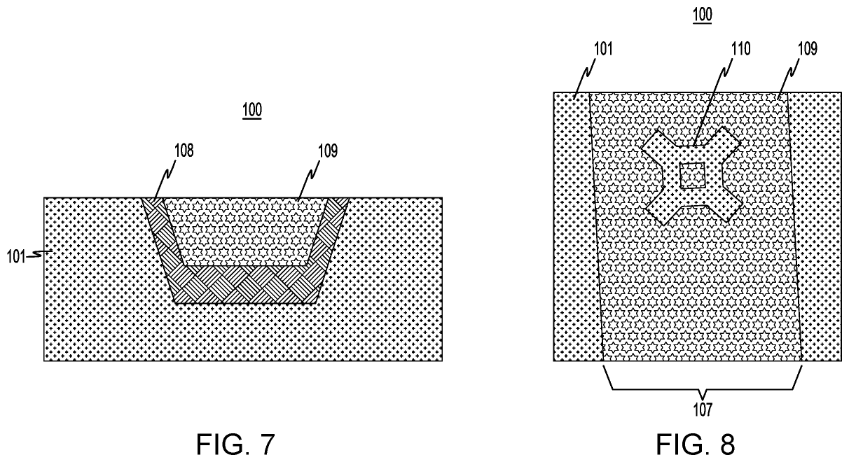

Referring to FIG. 2, a dielectric layer 102 including, but not necessarily limited to silicon oxide (SiOₓ), where x is, for example, 2 in the case of silicon dioxide (SiO₂), or 1.99 or 2.01, low-temperature oxide (LTO), high-temperature oxide (HTO) (also referred to herein as “thermal oxide”), flowable oxide (FOX), silicon oxycarbide (SiOC) or some other dielectric, is formed on the semiconductor substrate 101. Another dielectric layer 103 including, but not necessarily limited to, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) or other dielectric, is formed on the dielectric layer 102. The dielectric material of dielectric layers 102 and 103 can be deposited using deposition techniques including, but not limited to, chemical vapor deposition (CVD), plasma enhanced CVD (PECVD), radio-frequency CVD (RFCVD), physical vapor deposition (PVD), atomic layer deposition (ALD), molecular layer deposition (MLD), molecular beam deposition (MBD), pulsed laser deposition (PLD), liquid source misted chemical deposition (LSMCD), and/or sputtering. In a non-limiting illustrative embodiment, the dielectric layers 102 and 103 each have a thickness of 50 nanometers. As discussed in more detail in connection with FIGS. 4 and 7, the dielectric layers 102 and 103 are eventually removed, and may be referred to herein as sacrificial dielectric layers.

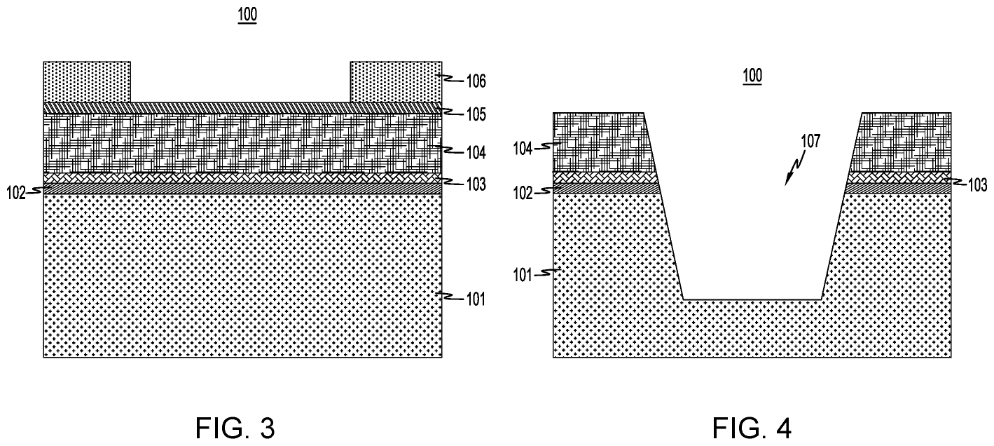

Referring to FIG. 3, an organic planarization layer (OPL) 104 is formed on the dielectric layer 103 and a lithography stack comprising one or more additional sacrificial dielectric layers 105 and a photoresist pattern comprising a plurality of photoresists 106 are formed on the OPL 104. According to an embodiment, the one or more additional sacrificial dielectric layers 105 comprise a silicon anti-reflective coating (SiARC) layer and/or a layer comprising the same or similar to that of the dielectric layers 102 and/or 103, which are also sacrificial dielectric layers.

The OPL 104 comprises, but is not necessarily limited to, an organic polymer including C, H, and N. In an embodiment, the OPL material can be free of silicon (Si). According to an embodiment, the OPL material can be free of Si and fluorine (F). As defined herein, a material is free of an atomic element when the level of the atomic element in the material is at or below a trace level detectable with analytic methods available in the art. Non-limiting examples of the OPL material include JSR HM8006, JSR HM8014, AZ UM10M2, Shin Etsu ODL, or other similar commercially available materials from such vendors as JSR, TOK, Sumitomo, Rohm & Haas, etc. The OPL 104 can be deposited, for example, by spin coating, to a thickness of about 100 nanometers-about 200 nanometers.

Referring to FIG. 4, portions of the semiconductor structure 100 left exposed by the photoresists 106 are removed to form a trench 107 in the semiconductor substrate 101. As can be seen in FIGS. 3 and 4, a central portion of the one or more additional sacrificial dielectric layers 105 is left exposed by the photoresists 106. Upon removal of the one or more additional sacrificial dielectric layers 105, a central portion of the OPL 104 exposed and removed. Then, upon removal of the OPL 104, a central portions of the dielectric layers 102 and 103 are exposed and removed, thereby exposing a central portion of the semiconductor substrate 101, which is removed to form the trench 107.

The photoresists 106 are formed on the one or more additional sacrificial dielectric layers 105 to expose a region corresponding to where the trench 107 is to be formed. The photoresists 106 have a thickness in the range of about 80 nanometers to about 110 nanometers, and horizontal widths necessary to result in the desired dimensions of the trench 107.

Referring to FIG. 4, exposed portions of the one or more additional sacrificial dielectric layers 105, OPL 104, dielectric layer 103, dielectric layer 102 and semiconductor substrate 101 not under the photoresists 106 are removed by one or more etching processes. For example, the etching processes are performed using, for example, a fluorocarbon reactive ion etch (RIE) to remove the exposed portions of the one or more additional sacrificial dielectric layers 105, OPL 104, dielectric layer 103 and dielectric layer 102 down to the semiconductor substrate 101. The portions of the semiconductor substrate 101 to form the trench 107 are removed using one or more etching processes.

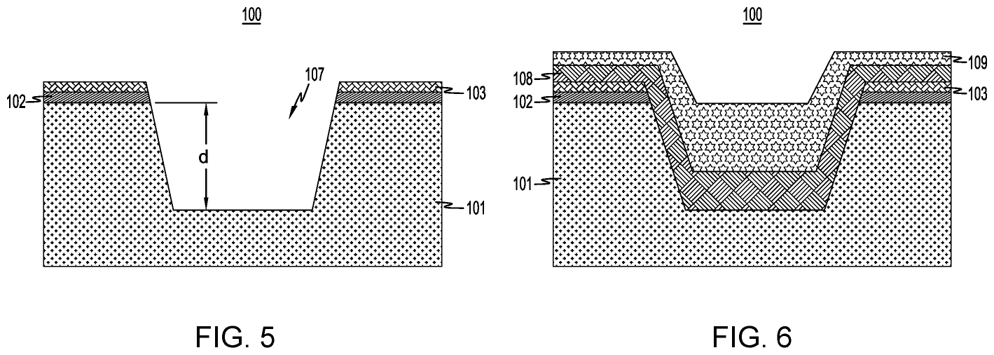

In addition, as shown in FIG. 4, following formation of the trench 107, the photoresists 106 and remaining portions of the one or more additional sacrificial dielectric layers 105 are removed. Then, referring to FIG. 5, a remaining portion of the OPL 104 is removed in, for example, an ashing process. The remaining portions of the one or more additional sacrificial dielectric layers 105 and OPL 104 are removed using, for example, oxygen plasma, nitrogen plasma, hydrogen plasma or other carbon strip or ashing processes. The stripping process causes minimal or no damage to the remaining layers. A resulting depth (d) of the trench 107 measured from a top surface of the semiconductor substrate 101 is in the range of about 200 nanometers to about 500 nanometers.

One or more alignment marks 110 (see FIG. 8), are formed in the bottom surface of the trench 107. The alignment marks 110 (also referred to as “fiducials”) are not necessarily limited to the star-like pattern shown in FIG. 8, and may be formed in a variety of different patterns. The alignment marks 110 (fiducials) are formed by etching the alignment mark pattern into the bottom surface of the trench 107. As can be understood, the etching creates recesses in the bottom surface of the trench 107 where the pattern is formed. For example, the “X” and “square” shapes of the alignment mark 110 are created by etching the patterns into the bottom surface of the trench 107. As can be understood, necessary masking must be performed so that the correct pattern is etched into the semiconductor substrate 101 at the bottom surface of the trench 107.

Referring to FIG. 6, a first trench dielectric layer 108 including, but not necessarily limited to, an oxide, and a second trench dielectric layer 109 including, but not necessarily limited to, a nitride, are deposited in the trench 107 on the one or more alignment marks 110 in the trench 107, and on the semiconductor structure 100 including the remaining portions of the dielectric layers 102 and 103 on a top surface of the semiconductor substrate 101. In an illustrative embodiment, the first trench dielectric layer 108 comprises an HTO (e.g., thermal oxide) such as, for example, silicon oxide (SiOₓ), which can be formed using deposition techniques including, but not limited to, CVD, PECVD, RFCVD, PVD and/or rapid thermal chemical vapor deposition (RTCVD) at temperatures in the range of about 200° ° C. to about 400° C. As can be seen in FIG. 6, the first trench dielectric layer 108 is conformally formed on side and bottom surfaces of the trench 107 and on top surfaces of the dielectric layer 103. The second trench dielectric layer 109 is formed on the first trench dielectric layer 108 and includes, for example, SiN, SiON, SiCN, BN, SiBN, SiBCN, SiOCN or other dielectric, and can be deposited using the same or similar deposition techniques as those used for dielectric layer 103. In an illustrative embodiment, the second trench dielectric layer 109 comprises a thermal nitride such as, for example, SiN, which can be formed using deposition techniques including, but not limited to, CVD, PECVD, RFCVD, PVD and/or RTCVD at temperatures in the range of about 200° C. to about 400° C. As can be seen, the second trench dielectric layer 109 fills in a remaining portion of the trench 107 not filled in by the first trench dielectric layer 108, and is formed on top surfaces of the first trench dielectric layer 108 outside of the trench 107. Referring to FIG. 7, a planarization process such as, for example, CMP is performed following formation of the first and second trench dielectric layers 108 and 109. The planarization process planarizes a top surface of the semiconductor substrate 101 and portions of the first and second trench dielectric layers 108 and 109 in the trench 107. The planarization process removes the dielectric layers 102 and 103, and the first and second trench dielectric layers 108 and 109 from the top surface of the semiconductor substrate 101. In an alternative embodiment, the trench 107 is filled with the first trench dielectric layer 108, and the second trench dielectric layer 109 is omitted.

FIG. 8 is a schematic top view illustrating an alignment mark 110 in the trench 107 following formation of the first and second trench dielectric layers 108 and 109 and planarization of the semiconductor substrate 101. The depth range of about 200 nanometers to about 500 nanometers of the trench 107 results in high resolution of the one or more alignment marks 110 when the trench 107 is filled with the first and second trench dielectric layers 108 and 109. After the one or more alignment marks 110 are etched into the material of the bottom surface of the trench 107 (e.g., silicon), the structures are filled with dielectric film (e.g., first and second trench dielectric layers 108 and 109) and then CMP is done to planarize the semiconductor substrate 101.

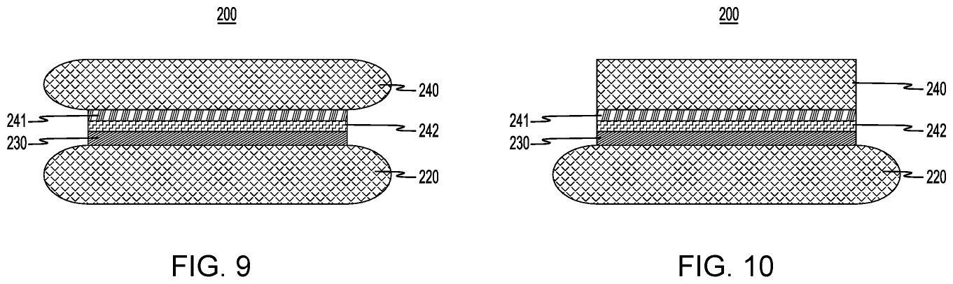

Referring to FIG. 9, a semiconductor structure 200 includes a device substrate 240 and a handler substrate 220. The device substrate 240 is bonded to the handler substrate 220 in a thermocompression direct bonding process. The device substrate 240 comprises a buried dielectric layer 241 and a semiconductor-on-insulator substrate 242. The device substrate 240 comprises a semiconductor material including, but not limited to, Si, SiGe, SiC, Si:C, SiGeC, SiGe:C, III-V, II-V compound semiconductor or other like semiconductor. The semiconductor-on-insulator substrate 242 includes, but is not limited to, an SOI, SGOI or III-V-on-insulator substrate. The buried dielectric layer 241 includes a buried insulating layer, such as, for example, a buried oxide layer, buried nitride layer or buried aluminum oxide layer.

The handler substrate 220 has the same configuration and materials as or a similar configuration and materials to the semiconductor substrate 101 described hereinabove, including the trench 107, first and second trench dielectric layers 108 and 109, and one or more alignment marks 110. In an illustrative embodiment, the semiconductor-on-insulator substrate 242 also includes a configuration and materials the same as or similar to the semiconductor substrate 101 described hereinabove, including the trench 107, first and second trench dielectric layers 108 and 109, and one or more alignment marks 110. Alternatively, the handler substrate 220 and not the semiconductor-on-insulator substrate 242 includes the configuration and materials the same as or similar to the semiconductor substrate 101 described hereinabove. The one or more alignment marks 110 are used to align the handler substrate 220 with the semiconductor-on-insulator substrate 242 during the bonding process. In illustrative embodiments, the handler substrate 220 further comprises one or more FinFET and/or vertical FET (VFET) structures, and the semiconductor-on-insulator substrate 242 includes one or more nanosheet and/or stacked nanosheet transistor structures.

A bonding dielectric layer 230 is disposed between the handler substrate 220 and the semiconductor-on-insulator substrate 242. The bonding dielectric layer 230 comprises, for example, a first bonding oxide layer (not shown) from the semiconductor-on-insulator substrate 242 (e.g., on the semiconductor-on-insulator substrate 242) and a second bonding oxide layer from the handler substrate 220 (e.g., on the handler substrate 220), which together form the bonding dielectric layer 230. In a non-limiting illustrative embodiment, the first and second bonding oxide layers are each about 1 μm thick, so that a total thickness of the bonding dielectric layer 230 is about 2 μm. The handler substrate 220 is bonded to the semiconductor-on-insulator substrate 242 (and underlying buried dielectric layer 241 and device substrate 240) via the bonding dielectric layer 230. In connection with the bonding process, the first and second bonding oxides undergo a thermocompression direct bonding process to form the bonding dielectric layer 230.

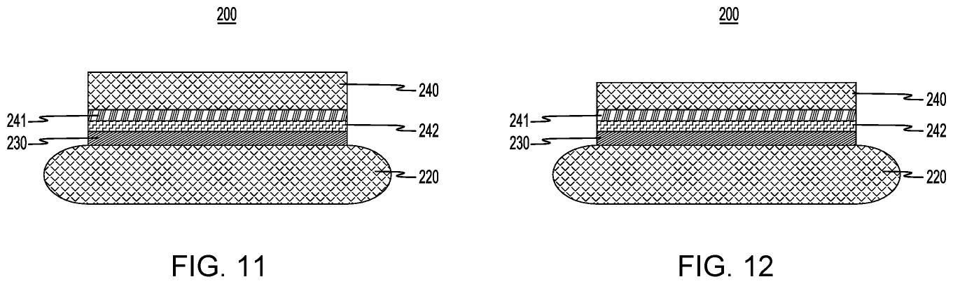

Referring to FIG. 10, edge trimming of the device substrate 240 is performed to remove side portions of the device substrate 240. Then, as shown in FIG. 11, a grinding process is performed to reduce a vertical thickness of the device substrate 240 to, for example, about 15 μm. Then, referring to FIG. 12, a planarization process such as, for example, CMP, is performed to further reduce the vertical thickness of the device substrate 240 to, for example, about 14 μm.

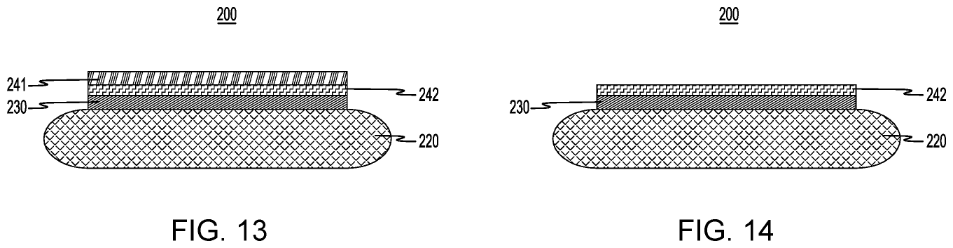

Referring to FIG. 13, a remaining portion of the device substrate 240 is removed using, for example, a RIE process that selectively removes the material (e.g., silicon) of the device substrate 240. Then, referring to FIG. 14, the buried dielectric layer 241 is removed using, for example, another RIE process including, for example, an Ar/CHF₃ based chemistry. Then, subsequent processing such as, for example, metallization and contact formation can be performed.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. An example integrated circuit includes one or more semiconductor devices with the above-described alignment mark and dielectric layer configuration.

As noted above, illustrative embodiments correspond to methods for forming high resolution alignment marks in a trench filled with one or more dielectric layers, along with illustrative apparatus, systems and devices formed using such methods. The non-metal alignment marks are instrumental for use in fabricating stacked FETs. The dielectric layers deposited in a trench on and around the alignment marks provide for high contrast/high resolution marks, wherein the resolution of the alignment marks is able to be controlled based on the depth of the trench. For example, a deeper trench can increase the resolution of an alignment mark at the bottom of a dielectric-filled trench.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as +5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a semiconductor substrate comprising a trench;
at least one alignment mark in a bottom surface of the trench; and
one or more dielectric layers disposed in the trench and on the at least one alignment mark.

2. The semiconductor structure of claim 1, wherein the one or more dielectric layers comprise a thermal dielectric layer.

3. The semiconductor structure of claim 2, wherein the one or more dielectric layers comprise a thermal oxide layer.

4. The semiconductor structure of claim 3, wherein the one or more dielectric layers further comprise a thermal nitride layer.

5. The semiconductor structure of claim 2, wherein the one or more dielectric layers further comprise an additional dielectric layer disposed on the thermal dielectric layer.

6. The semiconductor structure of claim 1, wherein a depth of the trench is in a range of about 200 nanometers to about 500 nanometers.

7. The semiconductor structure of claim 1, wherein the at least one alignment mark comprises one or more recesses in the bottom surface of the trench, and wherein the one or more dielectric layers fill the one or more recesses.

8. The semiconductor structure of claim 1, further comprising an additional semiconductor substrate bonded to the semiconductor substrate.

9. The semiconductor structure of claim 8, further comprising a bonding dielectric layer disposed between the semiconductor substrate and the additional semiconductor substrate.

10. The semiconductor structure of claim 1, wherein the semiconductor substrate comprises a handler substrate.

11. A method of forming a semiconductor device, comprising:
forming a trench in a semiconductor substrate;
forming at least one alignment mark in a bottom surface of the trench; and
forming one or more dielectric layers in the trench on the at least one alignment mark.

12. The method of claim 11, wherein forming the trench comprises:
depositing at least one sacrificial dielectric layer on the semiconductor substrate;
depositing an organic planarization layer on the at least one sacrificial dielectric layer; and
forming at least one photoresist on the organic planarization layer.

13. The method of claim 12, wherein forming the trench further comprises using the at least one photoresist as a mask and etching portions of the organic planarization layer, the at least one sacrificial dielectric layer and the semiconductor substrate left exposed by the at least one photoresist.

14. The method of claim 13, further comprising removing the at least one photoresist and the organic planarization layer, wherein the one or more dielectric layers are formed in the trench following removal of the at least one photoresist and the organic planarization layer.

15. The method of claim 11, wherein forming the one or more dielectric layers in the trench comprises performing a thermal oxidation process to form a thermal oxide layer on the at least one alignment mark.

16. The method of claim 15, wherein forming the one or more dielectric layers in the trench further comprises depositing a nitride layer on the thermal oxide layer.

17. The method of claim 11, further comprising planarizing the semiconductor substrate to remove portions of the one or more dielectric layers from a top surface of the semiconductor substrate.

18. The method of claim 17, further comprising:
forming a bonding dielectric layer on the semiconductor substrate; and
bonding the semiconductor substrate to an additional semiconductor substrate via the bonding dielectric layer, wherein the at least one alignment mark is used to align the semiconductor substrate with the additional semiconductor substrate.

19. A semiconductor structure, comprising:
a handler substrate; and
a device substrate bonded to the handler substrate;
wherein the handler substrate comprises:
a trench;
at least one alignment mark in a bottom surface of the trench; and
one or more dielectric layers disposed in the trench and on the at least one alignment mark.

20. The semiconductor structure of claim 19, wherein the one or more dielectric layers comprise a thermal dielectric layer.
